(19) United States
(12) Patent Application Publication
(10) Pub. No.: US 2015/0138696 A1
(43) Pub. Date: May 21, 2015

(54) CONTROL SYSTEM FOR MODULAR JAIL CELLS

(71) Applicant: Accurate Control, Inc., Ripon, WI (US)

(72) Inventor: Thomas P. Rogers, Ripon, WI (US)

(73) Assignee: ACCURATE CONTROL, INC., Ripon, WI (US)

(21) Appl. No.: 14/082,268

(22) Filed: Nov. 18, 2013

(51) Int. Cl. H05K 7/00; H05K 13/00

(52) U.S. Cl. CPC H05K 7/00; H05K 13/00
USPC 361/679.01; 29/592.1

(57) ABSTRACT

A method and system for controlling the electrical systems contained within a modular jail cell. The system includes a local control panel that is positioned near a block of jail cells. The local control panel is connected to the electrical systems contained within each of the jail cells. The control wires and local control panel can be pre-wired to each of the electrical systems. The control panel is connected to a central control terminal through a network cable. Control signals from the control terminal can be sent to each of the individual local control panels through the network cable, thus eliminating the need for separate control wires extending from each electrical system to the centralized control panel.

### BACKGROUND

The present disclosure generally relates to the construction and control of multiple, modular jail cells. More specifically, the present disclosure relates to an electronic control system for controlling the multiple electrical systems in each of a plurality of jail cells.

Over the past years, there has been a substantial increase in the number of prison inmates in the prison systems across the country. As a result, prison overcrowding has become an increasingly important issue. To address this issue, additional jails and holding facilities are being built to provide additional space of the growing prison population. The cost of additional jails has resulted in increased expenditures by local and state governments. As a result, there has been an increasing desire to reduce the construction costs of new prisons and jails while still providing the same level of security and control of the individual jail cells. Pre-fabricated jail cells for jail systems have been developed to reduce the cost of construction. Although the physical structure of a pre-fabricated cell reduces construction costs, the control of the electrical systems within each cell still requires a rather significant amount of setup and testing.

Currently, modular, pre-fabricated jail cells are assembled to define a cell block of multiple units. Each individual jail cell includes a plurality of individual electrical systems, such as an intercom, door lock and lighting system. Control wires for each of these electrical systems run from the individual cell to a centralized equipment room. Within the centralized equipment room is a computer terminal that allows personnel to control each of the electrical systems in each of the individual jail cells. Although this centralized control has proven effective, an extremely large number of control wires must run from the centralized control room to each of the electrical systems in each of the plurality of jail cells. The complexity of the wiring results in increased construction costs and testing costs once the cell block has been created. Therefore, a need exists for a pre-fabricated jail cell that includes electrical systems that can be tested prior to installation and connected and controlled in a relatively efficient and inexpensive manner.

### SUMMARY

The present disclosure related to a control system for controlling the electrical systems contained within each one of a plurality of modular jail cells. More specifically, the present disclosure relates to a control system that includes a local control panel for a cell block of jail cells and a remotely located control terminal that communicates to each of the local control panels through a network cable.

The modular jail cell of the present disclosure includes pre-fabricated walls and a plurality of pre-wired electrical systems. These pre-wired electrical system can include a door lock, an intercom system and a lighting system. Each of the pre-wired electrical systems contained within each of the modular jail cells includes a control wire that extends from the jail cell. The modular jail cells can be assembled adjacent to each other to define a cell block that includes multiple jail cells. As an example, a cell block can include eight jail cells positioned adjacent to each other to define two floors.

Each cell block includes a single control panel that is positioned locally relative to the cell block. The control panel is used to distribute control signals to each of the electrical systems for the jail cells included in the cell block. Specifically, a control wire extends from the control panel to each of the electrical systems contained within the plurality of jail cells. Control signals sent through the control wires control the operation of the electrical systems, including the door lock, intercom and lighting system.

The control wires extending from the local control panel to the electrical systems contained within each of the jail cells are contained within a security raceway. The security raceway can be pre-wired to include all of the control wires. Preferably, each of the control wires includes an electrical connector that allows the control wires contained within the security raceway to be easily and quickly connected to the control wires for each of the electrical systems. In this manner, the connections to the control panel can be made without the need for any electrician or trained personnel.

The control panel associated with each of the cell blocks is in communication with a central control room through a network cable. The single network cable extending from the control room to the local control panel allows control signals from the control room to be sent to the local control panel. When the control signals are received at the local control panel, the control panel acts to carry out the control signals by sending control signals along the control wires to each of the electrical systems contained within the plurality of jail cells.

It is contemplated that the control system can be used with multiple, separate cell blocks each containing a plurality of jail cells. Each cell block includes a local control panel that is in communication with the control room through a network cable. In this manner, a control terminal in the central control room can control each of the electrical systems in the plurality of jail cells distributed in the multiple cell blocks. The system and method of the present disclosure eliminates the requirement for control wires to extend from each of the electrical systems in the modular jail cells directly to the centralized control room.

Various other features, objects and advantages of the invention will be made apparent from the following description taken together with the drawings.

### BRIEF DESCRIPTION OF THE DRAWINGS

The drawings illustrate the best mode presently contemplated of carrying out the disclosure. In the drawings:

FIG. 1 is a schematic illustration of the electrical control system for multiple groups of jail cells incorporating the subject matter of the present disclosure;

FIG. 2 is an end view of one of the blocks of cells incorporating a local control panel and security raceway;

FIG. 3 illustrates the distributed control system for a block of jail cells; and

FIG. 4 is a detailed view taken along line 4-4 of FIG. 3 illustrating the connection between the electrical systems of each jail cell and the security raceway.

### DETAILED DESCRIPTION

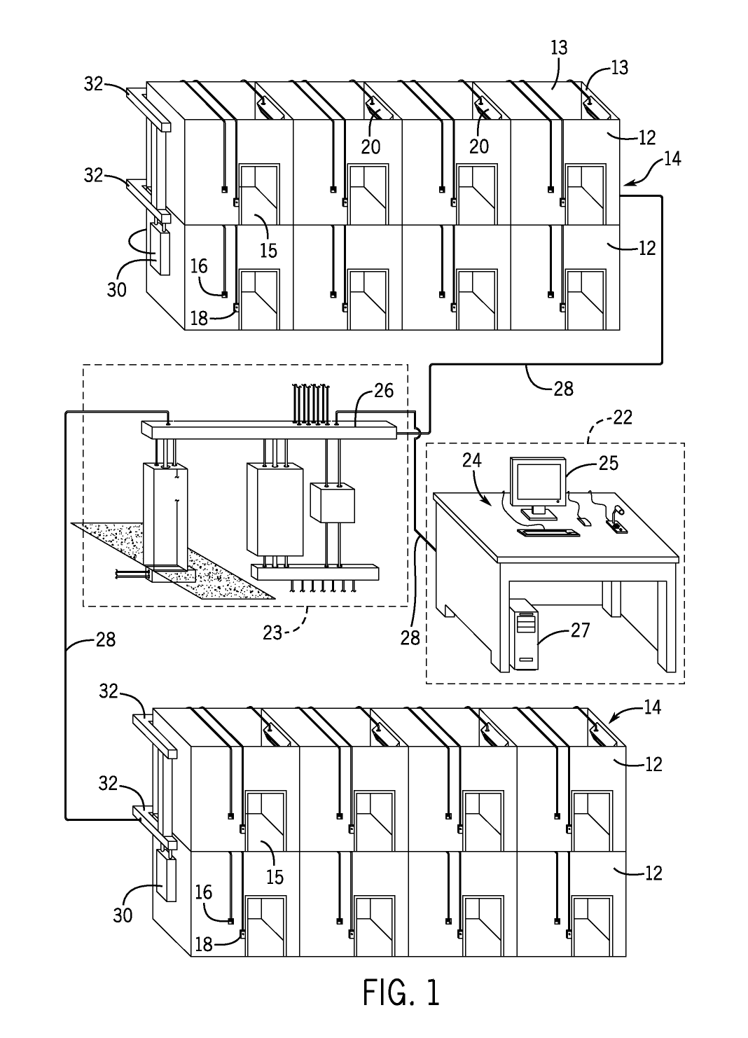

FIG. 1 illustrates the electrical control system 10 of the present disclosure. The electrical control system 10 provides a system that allows for control of various electrical systems for each individual jail cell 12 included in one or more cell blocks 14. In the embodiment shown in FIG. 1, the electrical control system 10 provides distributed control for the plurality of separately controlled electrical systems in two separate cell blocks that each include eight individual jail cells 12. Although two cell blocks 14 are shown in the embodiment of FIG. 1, it should be understood that only one cell block 14 could he utilized or three or more cell blocks 14 could be incorporated into the electrical control system 10 of the present disclosure.

In addition, each of the cell blocks 14 is shown including eight separate jail cells 12. However, each cell block 14 could include a different number of cells. In accordance with the present disclosure, each of the cell blocks 14 will have a multiple of eight individual jail cells. Thus, each cell block 14 could have either eight, sixteen, thirty-two or even sixty-four separate jail cells 12. In the embodiment illustrated in FIG. 1, the jail cells 12 are illustrated stacked to define two floors of jail cells. However, it should be understood that the jail cells 12 could all be positioned adjacent to each other on a single floor or could be constructed having more than two separate floors.

As illustrated in FIG. 1, each of the jail cells 12 is a pre-fabricated structure having four walls 13 and a front doorway 15. The doorway 15 includes a door (not shown) that is controlled to secure a prisoner with the jail cell 12. The pre-fabricated structures that form the jail cells 12 can be positioned adjacent to each other and stacked on top of each other to define the desired configuration for the jail cells.

Each jail cell 12 is a self-contained unit that can be constructed and the electrical systems in the cell tested offsite prior to installation at a prison or jail. Each jail cell 12 includes a plurality of electrical systems as well as an air supply system. The electrical systems associated with each of the jail cells 12 can include an intercom 16, a door lock 18 and a lighting system 20. Each of the separate electrical systems, including the intercom system 16, door lock system 18 and the lighting system 20 must be controllable from a location remote from the cell block 14. Although three electrical systems are shown, other electrical systems could be present.

In accordance with the present disclosure, the operation of each of the electrical systems is controlled from a central control room 22. The central control room 22 is typically located separate from an equipment room 23 that includes a variety of other types of equipment that may be needed to manage the operation of the prison or jail. The control room 22 typically includes at least one or more computer control terminals 24 that include a monitor 25 and CPU 27 that allow operational personnel to control the operation of the plurality of electrical systems contained within each one of the plurality of jail cells 12. As illustrated in FIG. 1, the computer terminal 24 is connected to a network cable 28 that extends from the control room 22 into the wiring gutter 26 contained in the equipment room 23. The wiring gutter 26 routes the network cable, along with other control wires, throughout the jail facility.

In the embodiment shown in FIG. 1, the network cable 28 connected to the control terminal 24 in the control room extends through the wiring gutter 26 to each of the two cell. blocks 14. The network cable 28 allows the control terminal 24 to communicate to both of the separate cell blocks 14.

Specifically, one of the network cables 28 extends from the control terminal 24 and is received at a local control panel 30 for each of the cell blocks 14. The local control panel 30 receives the control signals from the computer control terminal 24 through the respective network cable 28. The control panel 30, in turn, communicates with the electrical systems contained within each of the individual jail cells 12. In this manner, the central control terminal 24 can control operation of each of the individual electrical systems contained within the jail cells 12 through communication signals sent along the single network cable 28 to the individual local control panels 30. In the preferred embodiment of the disclosure, the local control panel 30 is a PLC/intercom control panel.

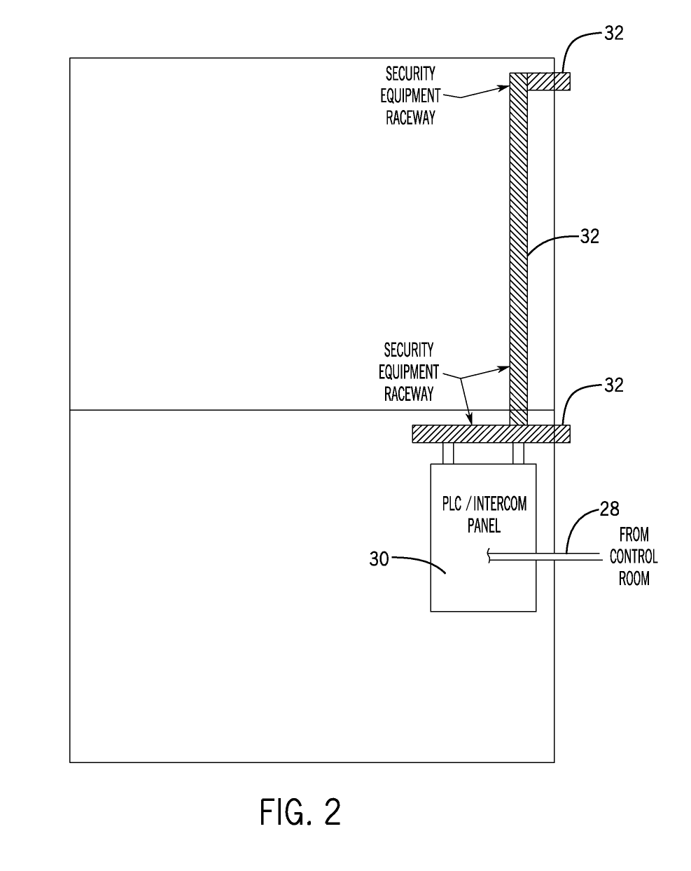

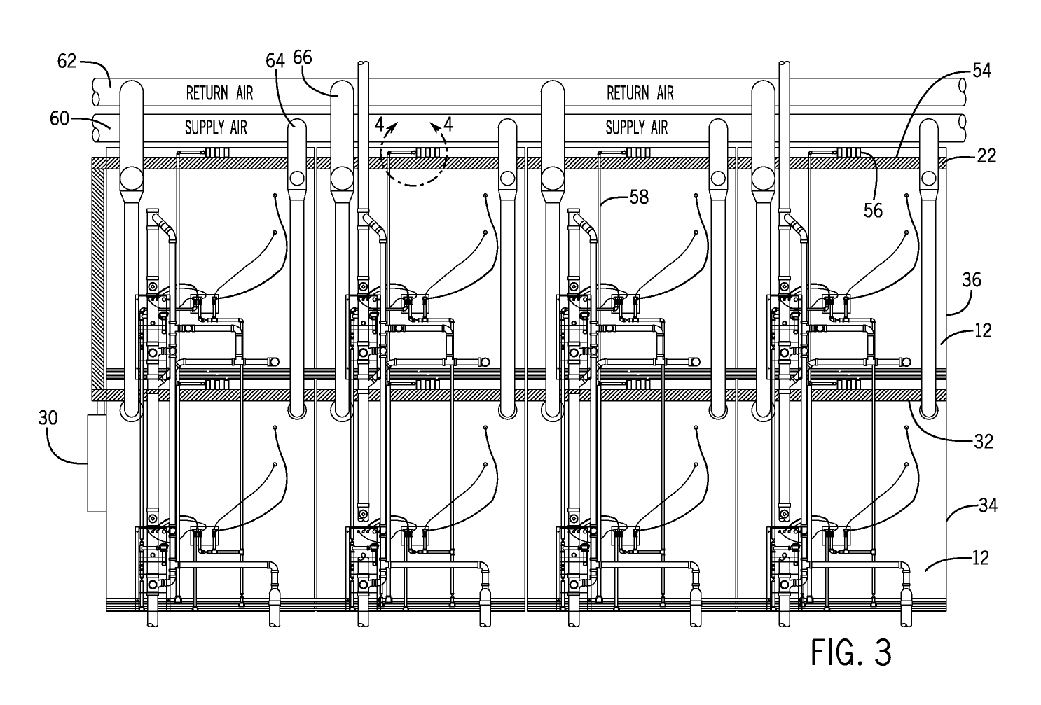

As can be understood in FIGS. 2 and 3, each of die local control panels 30 receives control wires that are contained within a security raceway 32 for the cell block 14. As illustrated in FIGS. 2 and 3, a security raceway 32 extends along the length of the lower row 34 of jail cells 12 as well as the upper row 36 of the jail cells 12. The separate security raceways 32 terminate at the local control panel 30 and are constructed to contain and protect the control wires for the electrical systems of the plurality of jail cells. Each of the individual raceways 32 include a plurality of individual control wires. The control wires 36 each have one end joined to the local control panel 30 and a second, opposite end connected to one of the electrical systems contained in the jail cell.

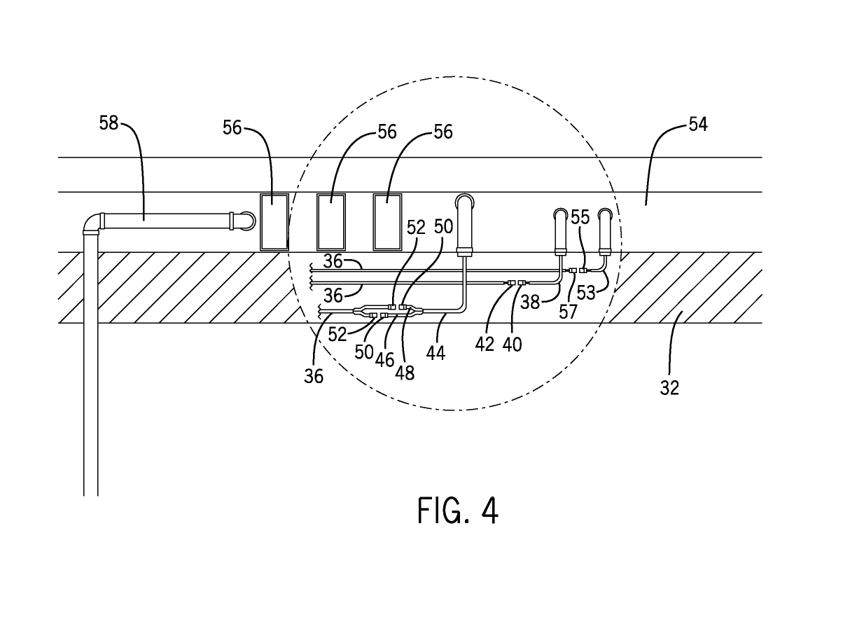

In the embodiment shown in FIG. 4, an intercom control wire 38 is connected to one of the control wires 36 through a first connector 40 and a second connector 42. The interaction between the first and second connectors 40, 42 allow for a quick and easy connection between the control wire 36 and the intercom control wire 38. In this manner, no trained personnel is required to make this connection since the two wires can simply plug together as illustrated.

In addition to the intercom control wire 38, a door lock control wire 44 is joined to one of the control wires 36 within the security raceway 32. The door lock control wire 44 includes a first wire 46 and a second wire 48 that each includes a separate connector 50. The connectors 50 join with a second connector 52 contained on two separate components of the control wire 36. Once again, the use of the individual connectors allows the wires to be joined together without having to utilize any special electrical connection or any trained personnel.

The lighting system includes a control wire 53 joined to one of the control wires 36 within the security raceway 32 by a connector 55 formed on the lighting control wire 53 and a mating connector 57 contained on the control wire 36. In this manner, control signals received at the local control panel can be distributed and used to control the lighting system within each of the individual jail cells.

Referring back to FIG. 3, the top end 54 of each jail cell 12 includes a series of knockout openings 56 that can be used to thread the control wires for the electrical systems contained within the individual jail cell for connection to the control wires 36 within the security raceway 32. In addition, a conduit 58 connects to a supply of electrical power to provide the power required to drive the electrical systems contained within each jail cell. The conduit 58, as illustrated in FIG. 3, extends between the pair of jail cells 12 stacked on top of each other to distribute electrical power throughout the entire cell block.

The connection between the series of individual control wires 36 and the respective electrical system within each of the modular cells allows the local control panel 30 to separately control the operation of the electrical systems in the jail cells. Since each of the cell blocks 14 includes a limited number of jail cells 12, the security raceway 32 can be pre-wired including all of the control wires. During installation, one end of the control wire is coupled to the local control panel 30 while the second end is connected to one of the electrical systems through use of the connectors, as described.

Referring back to FIG. 3, in addition to the electrical control system each of the cell blocks 14 includes a supply air conduit 60 and a return air conduit 62. The supply air conduit 60 receives a supply of fresh air from an HVAC system which is then distributed into each of the cells through a supply vent 64. Air from within each of the cells is returned to the return air conduit 62 through a return vent 66. During fabrication, each of the individual jail cells 12 is formed with the supply and return vents 64, 66 which can then be connected to the supply conduit 60 and the return air conduit 62, respectively.

During the initial construction of each of the individual jail cells 12, the jail cell is pre-wired for each of the electrical systems. As indicated, in the embodiment shown in the drawings, the electrical systems contained within each jail cell includes an intercom system, a door lock system and a lighting system. The control wires for each of the individual electrical systems contained within the jail cell can be formed having the respective control wire extending out of the top end of the jail cell, as illustrated in FIG. 4. Each of the control wires, including the intercom control wire 38 the door lock control wire 44, and the lighting control wire 53 extend out of the top end 54 and include a connector for connecting to the respective control wires 36 contained within the security raceway 32. During the initial construction of each jail cell at the manufacturing facility, the operation of the electrical systems can be tested and calibrated by connecting this equipment to each of the individual control wires 38, 44. Once the modular jail cell has been tested, the cell can be shipped to a detention facility and simply connected to one of the control wires that leads to the local control panel 30.

As discussed previously, each of the local control panels 30 is connected to a computer terminal 24 contained within the control room 22 through a single network cable 28. In this manner, the control terminal 24 can send control signals to each of the electrical systems contained within the individual jail cell 12. Unlike prior systems that connected each electrical system directly from the jail cell to the computer terminal 24, the system and method of the present disclosure utilizes network communication cables 28 extending between the control room 22 and the individual control panels 30. The elimination of the large number of individual control wires extending from each individual jail cell back to the control room 22 reduces the amount of time and materials required to set up the system of the present disclosure as compared to prior art modular jail cells.

This written description uses examples to disclose the invention, including the best mode, and also to enable any person skilled in the art to make and use the invention. The patentable scope of the invention is defined by the claims, and may include other examples that occur to those skilled in the art. Such other examples are intended to be within the scope of the claims if they have structural elements that do not differ from the literal language of the claims or if they include equivalent structural elements with insubstantial differences from the literal languages of the claims.

I claim:

1. A control system for controlling one or more electrical systems included in each one of a plurality of jail cells included in a group of jail cells, comprising:
a centralized control terminal located remotely from the group of jail cells;
a local control panel positioned near the group of jail cells, the local control panel being in communication with the control terminal; and
a plurality of control wires extending from the local control panel to the electrical systems in each of the jail cells.

2. The electronic control system of claim 1 further comprising a security raceway extending between the local control panel and each of the jail cells in the group of jail cells.

3. The electronic control system of claim 2 wherein the security raceway includes the control wires for each of the electrical systems associated with each of the jail cells.

4. The electronic control system of claim 3 wherein each of the electrical systems of each jail cell is connected to one of the control wires within the security raceway.

5. The electronic control system of claim 4 wherein the electrical systems each include at least a door lock and an intercom.

6. The electronic control system of claim 5 wherein the electrical systems include a lighting system.

7. The electronic control system of claim 1 wherein the local control panel is connected to the control terminal by a network cable such that the control terminal can control the electrical systems of each jail cell.

8. The electronic control system of claim 4 wherein each of the electrical systems is pre-wired in the jail cell and connected to the control wire within the security raceway.

9. The electronic control system of claim I wherein each group of jail cells includes at least eight jail cells.

10. A modular jail cell system comprising:
a plurality of individual jail cells, each jail cell being positioned adjacent to another jail cell and including a plurality of controllable electrical systems;
a single control panel associated with the plurality of jail cells, wherein the control panel controls the operation of the plurality of electrical systems;
a security raceway extending, from the single control panel to each of the jail cells; and
a plurality of control wires contained in the security raceway, wherein each of the electrical systems is connected to the control panel by one of the control wires.

11. The system of claim 10 wherein each of the electrical systems are connected to the control wires within the security raceway.

12. The system of claim 10 wherein the electrical systems of each jail cell include at least an intercom, a door lock and a lighting system.

13. The system of claim 10 wherein each of the electrical systems are pre-wired in the jail cell.

14. The system of claim 11 wherein electrical systems are connected to the control wires by a pair of mating connectors.

15. A method of controlling a plurality of electrical systems in each one of a plurality of jail cells, comprising:
providing a single control panel for the plurality of jail cells;
connecting the electrical systems of each of the jail cells to the control panel;
connecting the control panel to a centralized control terminal through a network wire; and
generating control signals from the control terminal to any one of the plurality of electrical systems, wherein the control signals are sent to the electrical system through the local control panel.

16. The method of claim 15 wherein each of the electrical systems are connected to the control panel by a control wire contained within a security raceway.

17. The method of claim 16 wherein each of the electrical systems is connected to the control panel through a connection to one of the control wires contained within the security raceway.
